(19) United States
(12) Patent Application Publication
(10) Pub. No.: US 2026/0341645 A1
(43) Pub. Date: Oct. 29, 2026

(54) SHAPED SILICON OUTER UPPER ELECTRODE FOR PLASMA PROCESSING

(71) Applicant: Lam Research Corporation, Fremont, CA (US)

(72) Inventors: William Dean Thompson, Plesanton, CA (US); Andrew D. Bailey, III, Milpitas, CA (US)

(21) Appl. No.: 19/107,011

(22) PCT Filed: Aug. 31, 2023
(86) PCT No.: PCT/US23/73229

§ 371 Date: Feb. 26, 2025

Related U.S. Application Data
(60) Provisional application No. 63/404,499, filed on Sep. 7, 2022.

(51) Int. Cl. H01J 37/32

(52) U.S. Cl. CPC H01J 37/32541

(57) ABSTRACT

An outer upper electrode for plasma processing. A shaped bottom surface and a top surface having a radial width, wherein a middle portion of the top surface has an oval shape. A cylindrical outline traversing a height of the outer upper electrode, wherein the middle portion of the top surface defines a top of the cylindrical outline. An inner diameter surface joining the top surface and the shaped bottom surface, wherein the inner diameter surface includes a transition edge. An outer diameter surface joining the top surface and the shaped bottom surface. A convex protrusion of the shaped bottom surface protruding below the transition edge of the inner diameter surface, wherein the convex protrusion includes a protrusion minima that is located in an interior region of the cylindrical outline.

### TECHNICAL FIELD

The present embodiments relate to semiconductor fabrication, and more specifically to systems and methods for implementing a shaped outer upper electrode with specific curvature for the purposes of modulating plasma density to tune wafer performance.

### BACKGROUND OF THE DISCLOSURE

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal provides power and is applied to at least one of the electrodes of the plasma processing chamber to form an electric field between the electrodes. The process gas is turned into plasma by the RF signal, thereby performing plasma etching on a predetermined layer disposed on the wafer. Unfortunately, during wafer processing, the plasma formation may cause non-uniformity of features along the extreme edge of the wafer thereby having an adverse affect on wafer performance during fabrication.

It is in this context that embodiments of the disclosure arise.

### SUMMARY

The present embodiments relate to methods and apparatus for a shaped outer upper electrode having a specific curvature for the purposes of modulating plasma density to tune wafer performance. Several inventive embodiments of the present disclosure are described below.

Embodiments of the present disclosure provide for an outer upper electrode used for plasma processing. The outer upper electrode including a shaped bottom surface. The outer upper electrode including a top surface having a radial width, wherein a middle portion of the top surface has an oval shape. The outer upper electrode including a cylindrical outline traversing a height of the outer upper electrode, wherein the middle portion of the top surface defines a top of the cylindrical outline. The outer upper electrode including an inner diameter surface joining the top surface and the shaped bottom surface, wherein the inner diameter surface includes a transition edge. The outer upper electrode including an outer diameter surface joining the top surface and the shaped bottom surface. The outer upper electrode including a convex protrusion of the shaped bottom surface protruding below the transition edge of the inner diameter surface, wherein the convex protrusion includes a protrusion minima that is located in an interior region of the cylindrical outline.

Other embodiments of the present disclosure provide for an upper electrode used for plasma processing. The upper electrode includes an inner upper electrode having a disk profile including a first top surface and a bottom surface that are joined by an outer surface. The bottom surface includes a sloped bottom surface extending from a lower edge of the outer surface to a central protrusion. The upper electrode includes an outer upper electrode adjacent to the inner upper electrode. The outer upper electrode includes a shaped bottom surface. The outer upper electrode includes second top surface having a radial width, wherein a middle portion of the second top surface has an oval shape. The outer upper electrode includes a cylindrical outline traversing a height of the outer upper electrode, wherein the middle portion of the second top surface defines a top of the cylindrical outline. The outer upper electrode includes an inner diameter surface joining the second top surface and the shaped bottom surface, wherein the inner diameter surface includes a transition edge. The outer upper electrode includes an outer diameter surface joining the second top surface and the shaped bottom surface. The outer upper electrode includes a convex protrusion of the shaped bottom surface protruding below the transition edge of the inner diameter surface, wherein the convex protrusion includes a protrusion minima that is located in an interior region of the cylindrical outline.

Still other embodiments of the present disclosure provide for a process chamber configured for plasma processing. The process chamber includes a pedestal assembly for supporting a substrate. The process chamber includes an inner upper electrode facing the pedestal assembly having a disk profile including a first top surface and a bottom surface that are joined by an outer surface. The bottom surface includes a sloped bottom surface extending from a lower edge of the outer surface to a central protrusion. The process chamber includes an outer upper electrode adjacent to the inner upper electrode. The outer upper electrode includes a shaped bottom surface. The outer upper electrode includes a second top surface having a radial width, wherein a middle portion of the second top surface has an oval shape. The outer upper electrode includes cylindrical outline traversing a height of the outer upper electrode, wherein the middle portion of the second top surface defines a top of the cylindrical outline. The outer upper electrode includes an inner diameter surface joining the second top surface and the shaped bottom surface, wherein the inner diameter surface includes a transition edge. The outer upper electrode includes an outer diameter surface joining the second top surface and the shaped bottom surface. The outer upper electrode includes a convex protrusion of the shaped bottom surface protruding below the transition edge of the inner diameter surface, wherein the convex protrusion includes a protrusion minima that is located in an interior region of the cylindrical outline. The outer upper electrode is an annular ring.

These and other advantages will be appreciated by those skilled in the art upon reading the entire specification and the claims.

### BRIEF DESCRIPTION OF THE DRAWINGS

The embodiments may best be understood by reference to the following description taken in conjunction with the accompanying drawings.

FIG. 1 illustrates an embodiment of a capacitive coupled plasma (CCP) processing system utilized for etching operations, in accordance with an implementation of the disclosure.

FIG. 2 illustrates how shapes of an inner upper electrode and an outer upper electrode affect wafer performance during plasma processing, in accordance with embodiments of the present disclosure.

FIG. 3A illustrates a top surface of an outer upper electrode that is shaped with specific curvature for the purposes of modulating plasma density to tune wafer performance during wafer fabrication, in accordance with one embodiment of the present disclosure.

FIG. 3B illustrates a cross section of the outer upper electrode shown in FIG. 3A that is shaped with specific curvature for the purposes of modulating plasma density to tune wafer performance during wafer fabrication, in accordance with one embodiment of the present disclosure.

FIG. 3C illustrates another cross section of the outer upper electrode shown in FIG. 3A including various exemplary configurations or modifications of a concave portion formed in a shaped bottom surface, in accordance with one embodiment of the present disclosure.

FIG. 3D illustrates another cross section of the outer upper electrode shown in FIG. 3A showing another exemplary configuration or modification of a convex portion formed in a shaped bottom surface, in accordance with one embodiment of the present disclosure.

FIG. 4 is an illustration of an interface between an inner upper electrode having a bottom surface that is sloped and an outer upper electrode having a shaped bottom surface, in accordance with one embodiment of the present disclosure.

FIGS. 5A-5C illustrate various offsets of an outer upper electrode having a shaped bottom surface with respect to an inner upper electrode having a bottom surface that is sloped at an interface introduce in FIG. 4, in accordance with one embodiment of the present disclosure.

### DETAILED DESCRIPTION

Although the following detailed description contains many specific details for the purposes of illustration, anyone of ordinary skill in the art will appreciate that many variations and alterations to the following details are within the scope of the present disclosure. Accordingly, the aspects of the present disclosure described below are set forth without any loss of generality to, and without imposing limitations upon, the claims that follow this description.

Generally speaking, the various embodiments of the present disclosure describe methods and apparatus for a shaped outer upper electrode having a specific curvature for the purposes of modulating plasma density to tune wafer performance. In particular, the outer upper electrode includes one or more curved regions to achieve directed plasma density control over the wafer during processing. That is, the outer upper electrode includes a shaped bottom surface that has curved transitions instead of sharp transitions (e.g., sharp edges). In some embodiments, the outer upper electrode includes a shaped bottom surface that is an extension or continuation of a sloped bottom surface of an inner upper electrode.

Advantages of the various embodiments, disclosing methods and apparatus for a shaped outer upper electrode include directed plasma density control over portions of a wafer. The ability to tune plasma density over a wafer provides for improved performance at the edge of a substrate. For example, by shaping the outer upper electrode, plasma density across the substrate is tunable to achieve etch rate uniformity across the diameter of the wafer that continue towards the outer edge. This leads to increased yields (i.e., of semiconductor chips) for each wafer.

With the above general understanding of the various embodiments, example details of the embodiments will now be described with reference to the various drawings. Similarly numbered elements and/or components in one or more figures are intended to generally have the same configuration and/or functionality. Further, figures may not be drawn to scale but are intended to illustrate and emphasize novel concepts. It will be apparent, that the present embodiments may be practiced without some or all of these specific details. In other instances, well-known process operations have not been described in detail in order not to unnecessarily obscure the present embodiments.

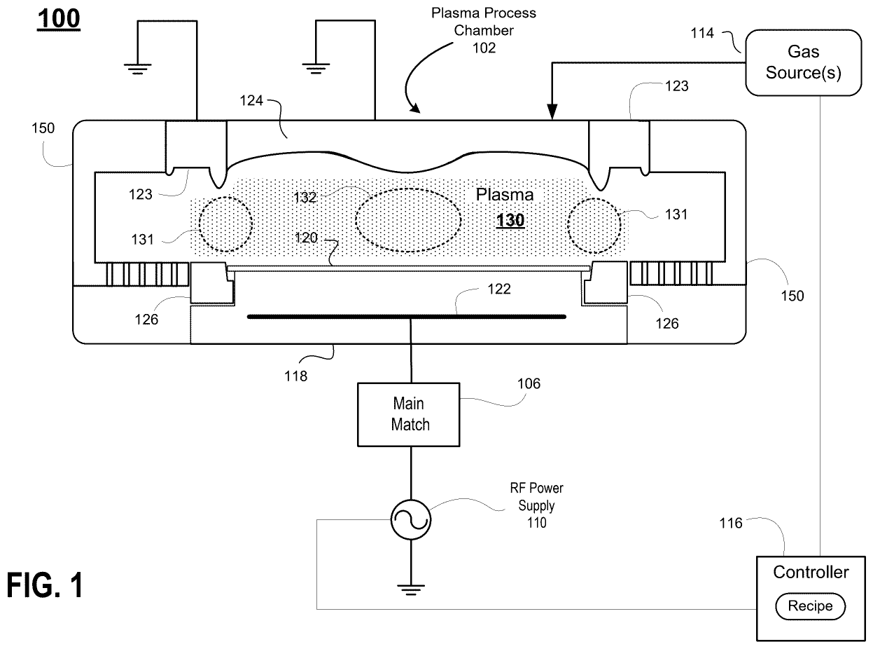

FIG. 1 illustrates an exemplary embodiment of a plasma processing system 100 utilized for operations including etching and/or depositing films, in accordance with one embodiment of the present disclosure. Plasma processing system 100 is configured to process a substrate or wafer 120, such as by performing plasma processing of the substrate 120. For purposes of illustration, plasma processing system 100 as shown in FIG. 1 may be utilized for etching operations and is configured as a capacitive coupled plasma (CCP) processing system,. However, in other embodiments, the plasma processing system 100 may be modified depending on design to generate plasma through various methods, such as inductively coupled plasmas (ICPs), etc. That is, embodiments of the present disclosure including a shaped outer upper electrode having a specific curvature for the purposes of modulating plasma density to tune wafer performance may be implemented on various plasma processing systems (e.g., CCPs, ICPs, etc.) and each of their configuration variations.

In particular, FIG. 1 illustrates an exemplary embodiment of the plasma processing system 100 utilized for etching operations that is configured as a CCP processing system, and includes a CCP plasma process chamber 102. The plasma process chamber 102 includes a substrate support or pedestal, such as an electrostatic chuck (ESC) 118, or magnetic chuck. In embodiments, the ESC may have several circular rings with different material types to achieve a certain capacitive coupling between the ESC and an optional edge ring 126. A lower electrode 122 may be embedded within the ESC 118. A substrate 120 may be placed on the pedestal for processing, wherein the substrate 120 is processed to make one or more semiconductor chips. Facing the pedestal is an upper electrode, which may be configured as an inner upper electrode 124 and an outer upper electrode 123. As shown, the inner upper electrode 124 may be coupled to ground. In other embodiments, the inner upper electrode 124 may be coupled to an RF power supply (e.g., supplying high frequency power, etc.). In some embodiments, the inner upper electrode 124 may be shaped to include a sloped bottom surface in order to modulate plasma density across a diameter of substrate 120. The inner upper electrode 124 may be configured with an extension that may be shaped as a ring, such as the outer upper electrode 123. In some embodiments, the outer upper electrode 123 may be coupled to ground. Between the upper electrode (i.e., the inner upper electrode 124 and the outer upper electrode 123) and the lower electrode 122 is a gap forming a processing volume within which a plasma 130 may be formed.

More particularly, the outer upper electrode 123 surrounds the inner upper electrode 124. It should be noted that the outer upper electrode 123 has an annular body, such as a circular body, or ring-shaped body, or dish-shaped body. In embodiments, the outer upper electrode 123 is shaped to tune plasma density of the plasma 130 across the substrate 120 to achieve etch rate uniformity, especially out towards the outer edge of the substrate 120. For example, increased plasma density may be achieved in region 131 of plasma 130, wherein region 131 may be a ring that is situated below the outer upper electrode 123. Similarly, increased plasma density may be achieved in region 132 of plasma 130 due to a protrusion in a center region of the inner upper electrode 124.

As shown, plasma processing chamber 102 of FIG. 1 may include a C-shroud 150 that extends from the upper electrode (e.g., inner upper electrode 124 and outer upper electrode 123) to the ESC 118 including the bottom electrode to provide additional plasma containment. The C-shroud may have a plurality of apertures to allow gas and byproducts to flow out of the C-shroud. The C-shroud may be grounded. In other embodiments, the plasma processing chamber may be configured differently to include confinement rings (not shown) for confining plasma 130 during etching operations.

In another embodiment, the gas source(s) 114 are connected to the plasma process chamber 102 and are configured to inject the desired process gas(es) into the plasma process chamber 102. As an example of plasma formation, after providing one or more RF signals to the ESC 118 and injecting process gas(es) into the plasma process chamber 102, plasma 130 is then formed between the upper electrode 124 and the ESC 118. The plasma 130 can be used to etch the surface of the wafer 120.

A source radio frequency (RF) power supply 110 is configured to provide RF power for purposes of plasma generation. The RF power supply 110 is coupled to an impedance match network 106 that is further coupled to the bottom electrode 122. The impedance match network matches impedances between the load (e.g., plasma chamber 102 and any connecting cabling) and a source (e.g., source RF power supply and any connecting cabling). That is, the match network enables dynamic tuning of power provided to the lower electrode 122 by matching impedances between the load and a source. The source RF power supply 110 is used typically to generate the plasma 130 using the process gases delivered from the gas source(s) 114. For example, the RF power supply 110 may be a high frequency (HF) RF generator configured to produce high frequencies ranging from and including 13 Megahertz (MHz) to 120 MHz. For example, the frequencies may be from and including 13 Megahertz (MHz) to 120 MHz. For example, the high frequency is a baseline frequency of 13.56 MHz or 27 MHz or 40 MHz or 60 MHz or 100 MHz. In embodiments, various configurations of power delivery may be implemented depending on the configuration of the plasma processing system 100, to include providing RF power using one or more signals at one or more frequencies that are delivered to the upper electrode and/or the lower electrode, providing bias power to the lower electrode, wherein the RF power and/or the bias power may be pulsed or continuous, etc.

In embodiments, the system may include a controller 116 that is used for controlling various components of the plasma processing system 100. In one example, the controller 116 can be connected to the RF power supply 110, to the gas source(s) 114 that are coupled to the plasma process chamber 102, and to other components. The controller 116 includes a processor, memory, software logic, hardware logic and input and output subsystems from communicating with, monitoring and controlling the plasma processing system 100. In some embodiments, the controller 116 includes one or more recipes including multiple set points and various operating parameters (e.g., voltage, current, frequency, pressure, flow rate, power levels, temperature, timing parameters, process gases, mechanical movement of the substrate 120, etc.) for operating the plasma processing system 100. For example, depending on the processing being performed, the controller 116 controls the delivery of process gases delivered from the gas source(s) 114 to achieve a designed processing condition, such as to etch features and/or deposit or form films over the substrate 120. The chosen gases are then distributed in a space volume defined between the upper electrode 124 and the substrate 120 resting over the ESC 118.

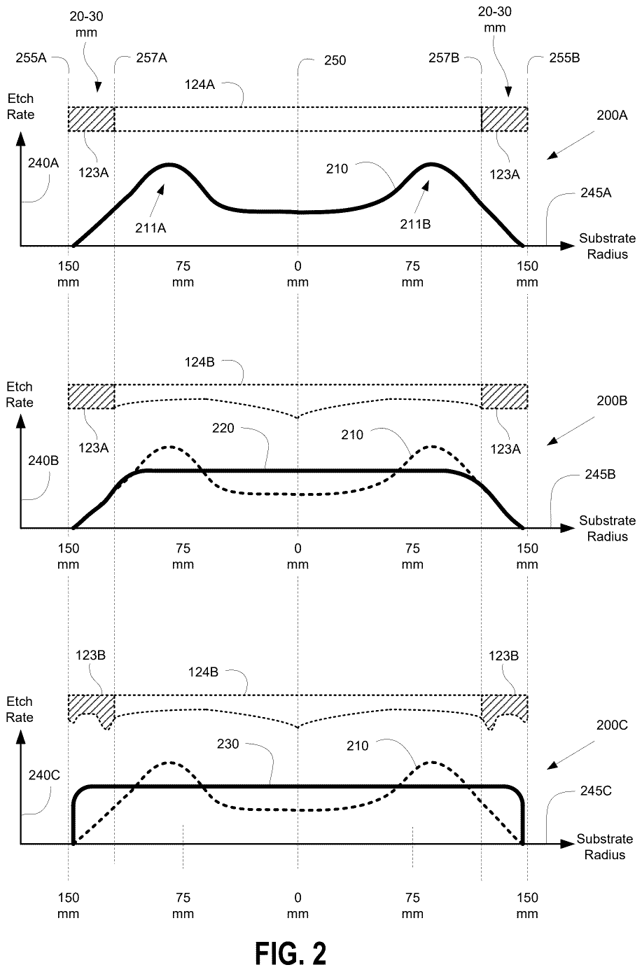

FIG. 2 illustrates how shapes of an inner upper electrode and an outer upper electrode affect wafer performance during plasma processing, in accordance with embodiments of the present disclosure. In particular, three graphs (e.g., 200A, 200B, and 200C) illustrate etch rates across a corresponding substrate (not shown) for various configurations of inner upper electrodes and/or outer upper electrodes. For purposes of illustration only, the substrate may have a diameter of 300 millimeters (mm) and correspondingly a radius of 150 mm. It is understood that embodiments of the present disclosure can be implemented on any size of wafer with appropriate modifications to the inner upper electrode and outer upper electrode (e.g., sizing of one or more of the inner and outer upper electrodes). Embodiments of the present disclosure include a shaped outer upper electrode that is configured to modulate plasma density in order to tune wafer performance (e.g., achieving etch rate uniformity across a surface of a wafer).

The three graphs (e.g., 200A, 200B, and 200C) are aligned for comparison purposes and share a center line 250 (e.g., center of the substrate), share an outer diameter shown by lines 255A and 255B, and share an outer radii region of the substrate that has an inner diameter shown by lines 257A and 257B. In embodiments, center line 250 may correspond with a center axis of each of the inner upper electrodes (e.g., 124A and 124B) and/or each of the outer upper electrodes (e.g., 123A and 123B). The outer radii region is also referred to as the exclusion region of the substrate, wherein the exclusion region typically experiences low etch rates but shows higher etch rates and more uniform etch rates (e.g., when compared to etch rates in a center region of the substrate) when implementing shaped outer upper electrodes of present embodiments. More particularly, outer radii region may be defined as a ring and on the left side of graph 200A is shown between lines 255A and 257A and on the right side of graph 200A is shown between lines 255B and 257B. For example, outer radii region may include the outer 20 to 30 mm of a substrate (e.g., a 300 mm substrate having a radius of 150 mm or substrates of different diameters). In embodiments, the radii of the inner diameter of the shaped upper outer electrode 123B may begin at a smaller radii that is within the outer radius of the substrate or may begin at larger radii beyond the outer radius of the substrate.

For example, graph 200A illustrates etch rates across a substrate for an upper electrode that has not been modified. That is, an inner upper electrode 124A is not shaped and includes a bottom surface that is flat and faces plasma. Also, an outer upper electrode 123A is not shaped and also includes a bottom surface that is flat and that is plasma facing. In some implementations, the bottom surfaces of the inner upper electrode 124A and the outer upper electrode 123A are coplanar. Vertical line 240A shows relative etch rates across one or more radii (e.g., between 0 to 150 mm for a 300 mm substrate) for a corresponding radial, wherein horizontal line 245A shows different radii for a corresponding radial of the substrate. In particular, line 210 shows the etch rate across the diameter of the substrate for an inner upper electrode that is not shaped and for an outer upper electrode that is not shaped. The etch rate shown in line 210 is mirrored about center line 250 and shows a relatively constant etch rate in a central region of the substrate (e.g., from the center of the substrate to radii between approximately 50-65 mm). A higher etch rate is shown by the humps 211A and 211B (between radii ranging between approximately 65 to 130 mm). The etch rate shown in line 210 drops off significantly to zero (0) in the exclusion region (i.e., between radii ranging approximately from 130 to 150 mm), such that the etch rate is very low in the outer radii region of the substrate. It is desired to have a uniform etch rate across radii of the substrate, which may be accomplished by shaped inner and outer upper electrodes in embodiments.

Graph 200B illustrates etch rates across a substrate for an upper electrode that has been partly modified. That is, an inner upper electrode 124B has been shaped and includes a sloped bottom surface that is shaped and faces plasma, wherein the sloped bottom surface is configured to modulate plasma density in a central region of the substrate in order to achieve uniform etch rates across the substrate (especially in the central region). In particular, the sloped bottom surface may include a central protrusion that may increase the plasma density of plasma over a central region of the substrate. In some embodiments, a thickness of the central protrusion of the inner upper electrode 124B along line 250 is greater than a thickness of the center region of the inner upper electrode 124A along line 250. For example, the central protrusion of the inner upper electrode 124B may extend towards the substrate by design to increase plasma density above the center region of the substrate to a desired level (e.g., to increase etch rates). On the other hand, an outer upper electrode 123A is not shaped and also includes a bottom surface that is flat and that is plasma facing (i.e., similar to that shown in graph 200A). For purposes of illustration, the central protrusion of the inner upper electrode 124B may extend below a bottom surface of the outer upper electrode 123A.

Vertical line 240B shows relative etch rates across one or more radii (e.g., between 0 to 150 mm for a 300 mm substrate) for a corresponding radial, wherein horizontal line 245B shows different radii for a corresponding radial of the substrate. In particular, line 220 shows the etch rate across the diameter of the substrate for an inner upper electrode that is shaped and for an outer upper electrode that is not shaped. Graph 200B compares etch rates between line 220 and line 210. In particular, the etch rate shown in line 220 is mirrored about center line 250 and shows that a relatively constant etch rate across a majority of the substrate (e.g., between radii of approximately 0 to 120 degrees). That is, the bottom surface of the inner upper electrode is shaped (e.g., central protrusion) to increase plasma density in the central region of the substrate (e.g., from the center of the substrate to radii between approximately 50-65 mm), and is shaped (sloped at the outer diameter) also to decrease plasma density for a region corresponding to humps 211A and 211B in graph 200A (e.g., radii ranging between approximately 65 to 130 mm of the substrate). Without wishing to be bound by theory or mechanism of action, it is believed that the shape and distance of a selected area of a bottom surface of the upper electrode (inner or outer) affects plasma density of plasma formed over the substrate. For example, plasma density may increase when a distance between the bottom surface of the upper electrode and the substrate becomes smaller. Similarly, plasma density may decrease when the distance between the bottom surface of the upper electrode and the substrate becomes greater.

As such, when comparing graph 200B to graph 200A, the shaped inner upper electrode 124B increases the etch rate in the central region of the substrate and lowers the etch rate for radii between approximately 65 to 130 mm of the substrate (e.g., corresponding to humps 211A and 211B of graph 200A). For example, the etch rate across the majority of the substrate (e.g., between radii of approximately 0 to 120 degrees) shown in line 220 may be higher than the etch rate across a central region of the substrate (e.g., between radii of approximately 0 to 50-65 degrees) shown in line 210. Also, between radii of approximately 0 to 50-65 degrees (e.g., previously corresponding to humps 211A and 211B related to graph 200A) the etch rate shown in line 220 may be lower than the corresponding etch rate shown in line 210. In that manner, a relatively constant etch rate is achieved between radii of approximately 0 to 120 degrees, as is shown in line 220 of graph 200B. Further, partly because the outer upper electrode 123A is not shaped, the etch rate shown in line 220 drops off significantly to zero (0) in the exclusion region (i.e., between radii ranging from 130 to 150 mm), such that the etch rate is very low in the outer radii region of the substrate. This etch rate may be similar to the etch rate shown in line 210 of graph 200A. It is desired to have a uniform etch rate across radii of the substrate, especially towards the outer region of the substrate, which may be accomplished by shaped inner and outer upper electrodes in embodiments and shown in graph 200C.

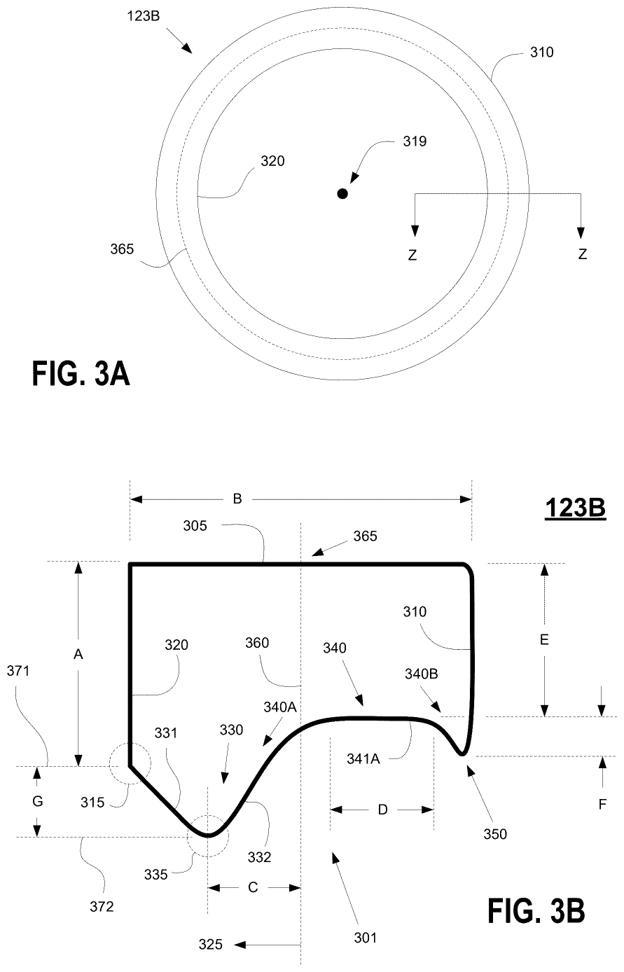

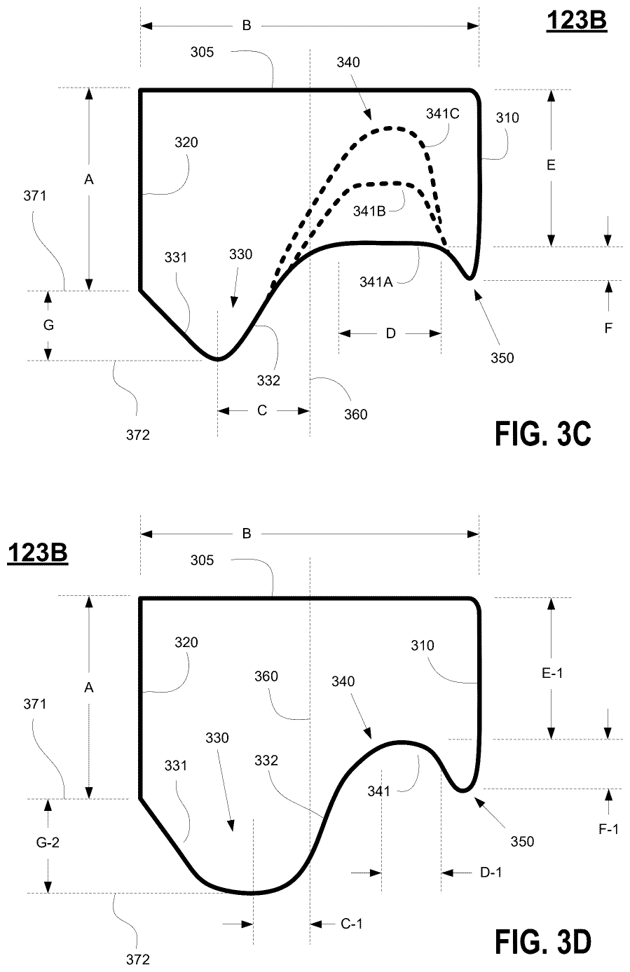

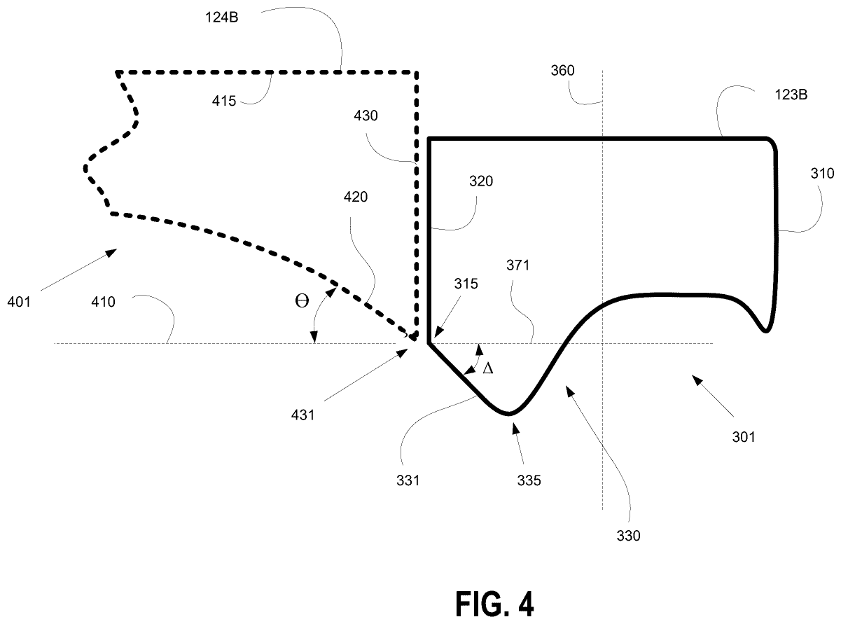

Graph 200C illustrates etch rates across a substrate for an upper electrode that has been modified. In particular, an inner upper electrode 124B has been shaped and includes a sloped bottom surface that is shaped and faces plasma, wherein the sloped bottom surface is configured to modulate plasma density in a central region of the substrate in order to achieve uniform etch rates across the substrate (especially in the central region). For example, the sloped bottom surface may include a central protrusion that may increase the plasma density of plasma over a central region of the substrate. Inner upper electrode 124B has been fully described in relation to graph 200B. Also, an outer upper electrode 123B has been shaped and includes a bottom surface that is shaped and that is plasma facing, wherein the shaped bottom surface is configured for purposes of modulating plasma density (e.g., generally increasing) in an outer region (e.g., exclusion region) of the substrate. For example, the shaped bottom surface includes one or more of a convex protrusion, a concave portion that is adjacent to the convex protrusion, and/or an extension adjacent to the concave portion. For purposes of illustration, the lowest point of the central protrusion of the inner upper electrode 124B may be aligned with a lowest point (e.g., protrusion minima) of the convex protrusion of the outer upper electrode 123B in one embodiment. A more detailed description of the outer upper electrode 123B that is shaped is provided in FIGS. 3A-3D and FIG. 4.

Vertical line 240C shows relative etch rates across one or more radii (e.g., between 0 to 150 mm for a 300 mm substrate) for a corresponding radial, wherein horizontal line 245B shows different radii for a corresponding radial of the substrate. In particular, line 230 shows the etch rate across the diameter of the substrate for an inner upper electrode that is shaped and for an outer upper electrode that is also shaped. Graph 200C compares etch rates between line 230 and line 210 (of graph 200A corresponding to a non-shaped upper electrode). In particular, the etch rate shown in line 230 is mirrored about center line 250 and shows that a relatively constant etch rate across the entirety of the substrate (e.g., between radii of approximately 0 to 140-150 degrees), and especially into the exclusion region of the substrate. There is an extreme drop off of etch rate at the outer edge of the substrate (e.g., near 150 mm). In particular, as previously described the bottom surface of the inner upper electrode 124B is shaped to increase plasma density in the central region of the substrate (e.g., from the center of the substrate to radii between approximately 50-65 mm), and is shaped (sloped at the outer diameter) also to decrease plasma density for a region corresponding to humps 211A and 211B in graph 200A (e.g., radii ranging between approximately 65 to 130 mm of the substrate). Also, the shaped bottom surface of the outer upper electrode 123B is shaped to increase plasma density in the exclusion region and towards an outer diameter surface. As previously introduced, without wishing to be bound by theory or mechanism of action, it is believed that the shape and distance of a selected area of a bottom surface of the upper electrode (inner or outer) can be designed to modulate plasma density of plasma formed over the substrate.

As such, when comparing graph 200C to graph 200A, the shaped inner upper electrode 124B increases the etch rate in the central region of the substrate and lowers the etch rate for radii between approximately 65 to 130 mm of the substrate (e.g., corresponding to humps 211A and 211B of graph 200A), as previously described when comparing graph 200B to graph 200A in the same areas. Also, because the outer upper electrode 12B is shaped (e.g., includes a shaped bottom surface) the etch rate in graph 200C in the exclusion region (e.g., between approximately 130-150 mm) is significantly increased from the etch rate in graph 200A. In that manner, a relatively constant etch rate is achieved across the substrate (e.g., between radii of approximately 0 to 150 mm), as is shown in line 230 of graph 200C, with only an extreme drop off in etch rate near the outer edge of the substrate (e.g., near 150 mm). As such, with the combination of the shaped inner upper electrode and the shaped outer upper electrode, a uniform etch rate across radii of the substrate is achieved, especially towards the outer edge and/or diameter of the substrate, as is shown in graph 200C.

FIGS. 3A-3B illustrate an exemplary shaped outer upper electrode 123B introduced in FIG. 2 including a shaped bottom surface for purposes of modulating and/or controlling plasma density over a substrate in order to tune wafer performance during processing. FIG. 3B illustrates a cross section of the outer upper electrode 123B taken along line Z-Z shown in FIG. 3A that is shaped with specific curvature for the purposes of modulating plasma density to tune wafer performance during wafer fabrication, in accordance with one embodiment of the present disclosure. The dimensions shown in FIGS. 3A-3B are intended to be variable, with values chosen for the dimension by design.

In particular, the outer upper electrode 123B is configured as an annular ring. The outer upper electrode has a top surface 305. The top surface 305 has a radial width that is defined by dimension “B” that is selectable. In embodiments dimension “B” may have a value between 10 mm to 20 mm, or may have a value between 20 mm to 30 mm, or may have a value between 30 mm to 40 mm, or may have a value between 40 mm to 50 mm, or may have a value between 50 mm to 60 mm, or may have a value between 60 mm to 70 mm. The top surface 305 has a middle portion 365 that may be configured with an oval and/or circular shape, and is located between the inner diameter surface 320 and the outer diameter surface 310 of the outer upper electrode 123B. In embodiments, the radii of the inner diameter surface 320 is selectable and may be smaller than or equal to or greater than the radii of the outer edge of a substrate. In embodiments, the radii of the inner diameter surface 320 (e.g., when used for processing a 300 mm wafer) may have a value between 110 mm to 120 mm, or may have a value between 120 mm to 130 mm, or may gave a value between 130 mm to 140 mm, or may have a value between 140 mm to 150 mm, or may have a value between 150 mm to 160 mm, or may have a value between 160 mm to 170 mm. In embodiments, the radii of the outer diameter surface 310 is selectable and may be smaller than or equal to or greater than the radii of the outer edge of a substrate. In embodiments, the radii of the outer diameter surface 310 (e.g., when used for processing a 300 mm wafer) may have a value between 140 mm to 160 mm, or may have a value between 150 mm to 180 mm, or may have a value between 150 mm to 200 mm, or may have a value between 150 mm to 220 mm, or may have a value between 150 mm to 240 mm, or may have a value between 150 mm to 250 mm. The middle portion 365 (e.g., in the shape of an oval) may define a center line 360 (at a corresponding radial) that forms a cylindrical outline of the outer upper electrode. Correspondingly, the radii of the center line 360 is selectable and may have a value that is smaller than or equal to or greater than the radii of the outer edge of a substrate. The cylindrical outline may traverse a height of the outer upper electrode 123B, wherein the height may have dimensions of “A” plus “G”. The middle portion 365 of the top surface 305 defines a top of the cylindrical outline. More particularly, the cylindrical outline includes a plurality of center lines intersecting with a plurality of radials extending from a center axis 319 of the shaped outer upper electrode 123B. Each center line is parallel to the center axis 319, wherein the center axis 319 is shown in FIG. 3A going into and out of the page. Each of the plurality of center lines vertically intersects with the middle portion 365 of the top surface. The cylindrical outline defined by line 360 may have an interior 325.

As shown, the shaped bottom surface 301 is shaped with specific curvature to achieve directed plasma density control over the substrate during processing and to modulate plasma density to tune wafer performance. The shaped bottom surface is configured to face plasma generated within the plasma chamber. In particular, the inner diameter surface 320 joins the top surface 305 and the shaped bottom surface 301. Further, the inner diameter surface includes a transition edge 315. A height of the inner diameter surface 320 between the top surface 305 and the transition edge 315 defined by line 371 is shown by dimension “A”. Also, an outer diameter surface 310 joins the top surface 305 and the shaped bottom surface 301.

The outer upper electrode 123B includes a convex protrusion 330 of the shaped bottom surface 301. The convex protrusion protrudes or extends below the transition edge 315 of the inner diameter surface 320. Specifically, the convex protrusion includes a downward sloped surface 331 extending from the transition edge 315 to the protrusion minima 335, and an upward sloped surface 332 extending from the protrusion minima 335 towards the cylindrical outline, and more particularly towards the center line 360 along a corresponding radial as shown in FIG. 3B, previously described. For example, the convex protrusion 330 has a height defined between the transition edge 315 defined by line 371 and the protrusion minima 335 defined by line 372, as further defined by dimension “G”. In one embodiment, the protrusion minima 335 is located in an interior region 325 of the cylindrical outline defined by the extension of middle 365 by center line 360 (e.g., taken along a corresponding radial). That is, the protrusion minima 335 is located to the left of center line 360, or towards a center of the substrate or towards the center axis 319, as shown in FIG. 3B. For example, the protrusion minima 335 may be located by a distance defined by dimension “C” from the center line 360.

The outer upper electrode 123B includes a concave portion 340 that is adjacent to the convex protrusion 330. The concave portion 340 is formed on a first side with an upward sloped surface 340A extending from the protrusion minima 335 towards the cylindrical outline, and more particularly towards the center line 360 (along a corresponding radial as shown in FIG. 3B) defined by the middle portion 365 of the top surface 305. The concave portion includes a mesa surface 341A that may be located above the transition edge 315 (defined by line 371). The mesa surface 341A may be defined by dimension “D”. As shown, the concave portion 340 is located towards the outer diameter surface 310 from the cylindrical outline and/or the center line 360 as shown in FIG. 3B. That is, at least a portion of the concave portion is located to the right of the cylindrical outline and/or center line 360.

In addition, the outer upper electrode may include an extension 350 protruding from the outer diameter surface 310 having a height of dimension “E”. For example, the extension is formed on a downward sloped surface 340B of a second side of the concave portion 340, and further extends below the outer diameter surface (e.g., below dimension “E”). A height of the extension 350 may be defined by dimension “F”.

FIG. 3C illustrates another cross section of the outer upper electrode 123B shown in FIG. 3A including various exemplary configurations or modifications of a concave portion formed in a shaped bottom surface, in accordance with one embodiment of the present disclosure. The outer upper electrode 123B has been previously described, wherein like referenced components of the outer upper electrode 123B shown in FIGS. 3A-3C have similar features and similar configurations. In particular, dimensions “A-F” may be modified to achieve desired effects.

In particular, the configuration of the concave portion 340 may be modified to achieve desired effects (e.g., desired etch rates in the exclusion region). As shown, the mesa surface may be modified, with varying widths (e.g., defined by dimension “D”), and varying heights (e.g., defined by dimension “E”). For example, mesa surface 341A (introduced in FIG. 3B) has the least height (e.g., is closer to the level of the transition edge 315 than to the top surface 305) and widest length, mesa surface 341B has a medium height, and mesa surface 341C has the greatest height (e.g., is closer to the top surface 305 than the transition edge 315 of the inner diameter surface 320) and the least length.

Also, the configuration of the convex protrusion 330 may be modified to achieve desired effects (e.g., desired etch rates in the exclusion region). For example, the height of the convex protrusion 330 may be modified, wherein the height is defined by dimension “G”. That is, the level of the protrusion minima defined by line 372 may be modified to be further away from the transition edge 315 or closer to the transition edge 315. Also, the width of the convex protrusion 330 may be modified. For example, the location of the protrusion minima 335 with respect to the cylindrical outline, or center line 360 along a corresponding radial, as defined by dimension “C” may be varied. For example, the protrusion minima may be closer to the cylindrical outline and/or the center line 360, or further away from the cylindrical outline and/or the center line 360. The height and width of the convex protrusion may affect the width of the concave portion (width defined by dimension “D”), and vice versa.

FIG. 3D illustrates another cross section of the outer upper electrode 123B shown in FIG. 3A showing an exemplary configuration or modification of a convex protrusion 330 and a concave portion 340 formed in a shaped bottom surface 301, in accordance with one embodiment of the present disclosure. The outer upper electrode 123B has been previously described, wherein like referenced components of the outer upper electrode 123B shown in FIGS. 3A-3D have similar features and similar configurations.

In particular, the configuration of the convex protrusion 330 may be modified to achieve desired effects (e.g., desired etch rates in the exclusion region). For example, the height of the convex protrusion 330 may be modified, wherein the modified height is shown by dimension “G-1”. As shown, the height of the convex protrusion 330 has increased between FIG. 3B (e.g., dimension “G”) and FIG. 3D (e.g., dimension “G-1”). Further, the location of the protrusion minima 335 may be modified, wherein the modified location is shown by dimension “C-1”. As shown, the location of the convex protrusion 330 has moved closer to the cylindrical outline, and more particularly the center line 360 (e.g., taken along a corresponding radial) between FIG. 3B (e.g., dimension “C”) and FIG. 3D (e.g., dimension C-1”).

Also, the configuration of the concave portion 340 may be modified to achieve desired effects (e.g., desired etch rates in the exclusion region). For example, the shape and height of the concave portion 340 may be modified, wherein the modified height is shown by dimension “E-1”. For example, the height of the concave portion 340 has decreased between FIG. 3B (e.g., dimension “E”) and FIG. 3D (e.g., dimension “E-1”). Further, the width of the concave portion 340 has decreased between FIG. 3B (e.g., dimension “D”) and FIG. 3D (dimension “D-1”). Also, the shape and height of the extension 350 may be modified, wherein the modified height is shown by dimension “F-1”. For example, the height of the extension 350 has increased between FIG. 3B (e.g., dimension “F”) and FIG. 3D (e.g., dimension “F-1”).

FIG. 4 is an illustration of an interface between an inner upper electrode 124B introduced in FIG. 2 having a bottom surface 420 that is sloped and an outer upper electrode 123B introduced in FIG. 2 having a shaped bottom surface 301, in accordance with one embodiment of the present disclosure. In particular, outer upper electrode 123B has been previously described, wherein like referenced components of the outer upper electrode 123B shown in FIGS. 3A-3C and FIG. 4 have similar features and similar configurations.

In particular, the inner upper electrode 124B may be configured with a disk profile, and includes a top surface 415 and a bottom surface 401 that are joined by an outer surface 430. The bottom surface 401 is configured to face plasma and/or a processing volume where plasma is formed, wherein the bottom surface is shaped to achieve directed plasma density control, as previously described. For example, the bottom surface 401 includes a sloped bottom surface 420 portion at the outer edge or region of the inner upper electrode including the outer surface 430. As shown, the sloped bottom surface extends from a lower edge 431 of the outer surface 430 to a central protrusion (not shown), wherein the central protrusion was previously described in relation to FIG. 2. More particularly, lower edge 431 may be defined by line 410. Further, the sloped bottom surface 420 at the lower edge 431 has an angle with respect to line 410 that is defined by angle theta (Θ).

In addition, the outer upper electrode 123B, as previously described, is located adjacent to the inner upper electrode 124B. For purposes of brevity and clarity, the outer upper electrode is configured as an annular ring and includes a shaped bottom surface 301 configured to face the plasma and/or a processing volume where plasma is formed. The outer upper electrode 123B includes a top surface 305. An inner diameter surface 320 joins the top surface 305 and the shaped bottom surface 301, wherein the inner diameter surface includes a transition edge 315. Also, the outer diameter surface 310 joins the top surface 305 and the shaped bottom surface 301. The outer upper electrode 123B includes a convex protrusion 330 of the shaped bottom surface protruding below the transition edge 315 of the inner diameter surface 320. The convex protrusion 330 includes a protrusion minima 335 at a level defined by line 371. As shown, the convex protrusion 330 includes a downward sloped surface 331 extending from the transition edge 315 of the inner diameter surface 320 to the protrusion minima 335.

In one embodiment, the sloped bottom surface 420 of the inner upper electrode 124B is continued by the downward sloped surface 331 of the shaped bottom surface 301 of the outer upper electrode 123B at an interface between the inner upper electrode and the outer upper electrode. In particular, at the interface the lower edge 431 of the outer surface 430 of the inner upper electrode 124B is adjacent to the transition edge 315 of the inner diameter surface 320 of the outer upper electrode 123B. More specifically, the downward sloped surface 331 of the convex protrusion 330 may be a continuation of the sloped bottom surface 420 of the inner upper electrode 124B at the interface (e.g., at the lower edge 431 of the inner upper electrode and the transition edge 315 of the outer upper electrode). That is, the downward sloped surface 331 of the shaped bottom surface 301 of the outer upper electrode 123B is a continuation of the sloped bottom surface 420 of the inner upper electrode 124B. As shown, the sloped bottom surface 420 of the inner upper electrode 124B has an angle with respect to line 410 that is defined by angle theta (Θ). Also, the downward sloped surface 331 of the outer upper electrode 123B has an angle with respect to line 371 that is defined by angle delta (Δ). At the interface in one embodiment, the angle theta (Θ) closely matches the angle delta (Δ), such that the first slope angle theta (Θ) of the sloped bottom surface 420 of the inner upper electrode 124B approximates a second slope angle delta (Δ) of the downward sloped surface 331 of the outer upper electrode 123B.

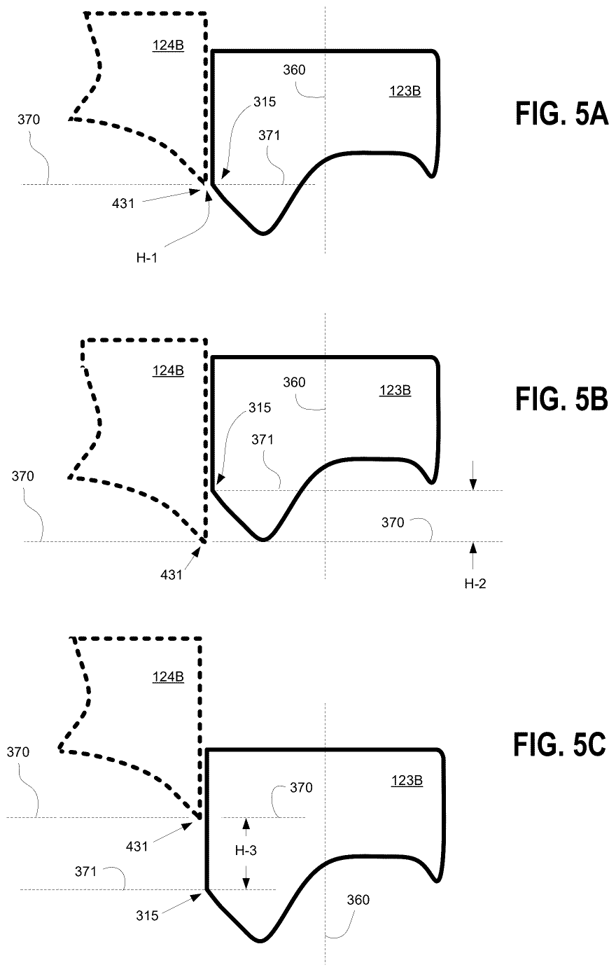

FIGS. 5A-5C illustrate various offsets of an outer upper electrode 123B having a shaped bottom surface with respect to an inner upper electrode 124B having a bottom surface that is shaped at an interface, in accordance with one embodiment of the present disclosure. For purposes of brevity and clarity, the outer upper electrode 123B is shaped and the inner upper electrode 124B is shaped, but it is understood that the outer upper electrode 123B could be paired with an inner upper electrode that is not shaped.

In particular, the offset of the outer upper electrode 123B from the inner upper electrode 124B is shown with respect to the interface between the lower edge 431 of the outer surface 430 of the inner upper electrode 124B and the transition edge 315 of the inner diameter surface 320 of the outer upper electrode 123B. As shown, the lower edge 431 of the outer surface 430 of the inner upper electrode 124B is defined by line 370. Also, the transition edge 315 of the inner diameter surface 320 of the outer upper electrode 123B is defined by line 371. The offset may be defined by a distance of dimension “H” between lines 370 and 371.

FIG. 5A shows little or no offset between the outer upper electrode 123B from the inner upper electrode 124B at the interface between the lower edge 431 of the outer surface 430 of the inner upper electrode 124B and the transition edge 315 of the inner diameter surface 320 of the outer upper electrode 123B. That is, the distance of dimension “H-1” between lines 370 and 371 in FIG. 5A is approximately zero (0).

FIG. 5B shows that the outer upper electrode 123B is offset from the inner upper electrode 124B in an upwards direction. That is, the transition edge 315 of the inner diameter surface 320 of the outer upper electrode 123B is offset from the lower edge 431 of the outer surface 430 of the inner upper electrode 124B by a distance of dimension “H-2” defined between lines 370 and 371. As shown, the transition edge 315 is above the lower edge 431 as shown in FIG. 5B, such that the transition edge 315 is further away from a corresponding substrate than the lower edge 431.

Further, FIG. 5C shows that the outer upper electrode 123B is offset from the inner upper electrode 124B in a downwards direction. That is, the transition edge 315 of the inner diameter surface 320 of the outer upper electrode 123B is offset from the lower edge 431 of the outer surface 430 of the inner upper electrode 124B by a distance of dimension “H-3” defined between lines 370 and 371. As shown, the transition edge 315 is below the lower edge 431 as shown in FIG. 5C, such that the transition edge 315 is closer to a corresponding substrate than the lower edge 431.

Without limitation, example systems implementing embodiments of the present disclosure may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma enhanced chemical vapor deposition (PECVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. An outer upper electrode used for plasma processing, comprising:
a shaped bottom surface;
a top surface having a radial width, wherein a middle portion of the top surface has an oval shape;
a cylindrical outline traversing a height of the outer upper electrode, wherein the middle portion of the top surface defines a top of the cylindrical outline;
an inner diameter surface joining the top surface and the shaped bottom surface, wherein the inner diameter surface includes a transition edge;
an outer diameter surface joining the top surface and the shaped bottom surface;
a convex protrusion of the shaped bottom surface protruding below the transition edge of the inner diameter surface,
wherein the convex protrusion includes a protrusion minima that is located in an interior region of the cylindrical outline.

2. The outer upper electrode of claim 1, wherein the convex protrusion includes:
a downward sloped surface extending from the transition edge to the protrusion minima; and
an upward sloped surface extending from the protrusion minima towards the cylindrical outline, wherein the cylindrical outline includes a plurality of center lines intersecting with a plurality of radials extending from a center axis of the outer upper electrode, wherein each of the plurality of center lines intersects with the middle portion of the top surface.

3. The outer upper electrode of claim 2,
wherein the downward sloped surface is a continuation of a sloped bottom surface at a lower edge of an outer surface of an inner upper electrode,
wherein the inner upper electrode is adjacent to the outer upper electrode.

4. The outer upper electrode of claim 1, further comprising:
a concave portion formed on a first side with a upward sloped surface extending from the protrusion minima towards the cylindrical outline, wherein the cylindrical outline includes a plurality of center lines intersecting with a plurality of radials extending from a center axis of the outer upper electrode, wherein each of the plurality of center lines intersects with the middle portion of the top surface,
wherein the concave portion is located towards the outer diameter surface from the cylindrical outline.

5. The outer upper electrode of claim 4,
wherein a mesa surface of the concave portion is closer to the top surface than the transition edge of the inner diameter surface.

6. The outer upper electrode of claim 4, further comprising:
an extension protruding from the outer diameter surface,
wherein the extension is formed on a second side of the concave portion.

7. The outer upper electrode of claim 1,
wherein the outer upper electrode is an annular ring.

8. An upper electrode used for plasma processing, comprising:
an inner upper electrode having a disk profile including a first top surface and a bottom surface that are joined by an outer surface, wherein the bottom surface includes a sloped bottom surface extending from a lower edge of the outer surface to a central protrusion;
an outer upper electrode adjacent to the inner upper electrode, wherein the outer upper electrode includes:
a shaped bottom surface;
a second top surface having a radial width, wherein a middle portion of the second top surface has an oval shape;
a cylindrical outline traversing a height of the outer upper electrode, wherein the middle portion of the second top surface defines a top of the cylindrical outline;
an inner diameter surface joining the second top surface and the shaped bottom surface, wherein the inner diameter surface includes a transition edge;
an outer diameter surface joining the second top surface and the shaped bottom surface;
a convex protrusion of the shaped bottom surface protruding below the transition edge of the inner diameter surface,
wherein the convex protrusion includes a protrusion minima that is located in an interior region of the cylindrical outline.

9. The outer upper electrode of claim 8, wherein the convex protrusion includes:
a downward sloped surface extending from the transition edge to the protrusion minima; and
an upward sloped surface extending from the protrusion minima towards the cylindrical outline, wherein the cylindrical outline includes a plurality of center lines intersecting with a plurality of radials extending from a center axis of the outer upper electrode, wherein each of the plurality of center lines intersects with the middle portion of the top surface.

10. The outer upper electrode of claim 9,
wherein the downward sloped surface is a continuation of the sloped bottom surface at the lower edge of the outer surface of the inner upper electrode.

11. The outer upper electrode of claim 10,
wherein a first slope of the sloped bottom surface of the inner upper electrode approximates a second slope of the downward sloped surface.

12. The outer upper electrode of claim 8, further comprising:
a concave portion formed on a first side with a upward sloped surface extending from the protrusion minima towards the cylindrical outline,
wherein the cylindrical outline includes a plurality of center lines intersecting with a plurality of radials extending from a center axis of the outer upper electrode, wherein each of the plurality of center lines intersects with the middle portion of the top surface,
wherein the concave portion is located towards the outer diameter surface from the cylindrical outline.

13. The outer upper electrode of claim 12,
wherein a mesa surface of the concave portion is closer to the second top surface than the transition edge of the inner diameter surface.

14. The outer upper electrode of claim 12, further comprising:
an extension protruding from the outer diameter surface,
wherein the extension is formed on a second side of the concave portion.

15. The outer upper electrode of claim 8,
wherein the outer upper electrode is an annular ring.

16. A process chamber, including:
a pedestal assembly for supporting a substrate;
an inner upper electrode facing the pedestal assembly having a disk profile including a first top surface and a bottom surface that are joined by an outer surface, wherein the bottom surface includes a sloped bottom surface extending from a lower edge of the outer surface to a central protrusion;
an outer upper electrode adjacent to the inner upper electrode, wherein the outer upper electrode includes:
a shaped bottom surface;
a second top surface having a radial width, wherein a middle portion of the second top surface has an oval shape;
a cylindrical outline traversing a height of the outer upper electrode, wherein the middle portion of the second top surface defines a top of the cylindrical outline;
an inner diameter surface joining the second top surface and the shaped bottom surface, wherein the inner diameter surface includes a transition edge;
an outer diameter surface joining the second top surface and the shaped bottom surface;
a convex protrusion of the shaped bottom surface protruding below the transition edge of the inner diameter surface,
wherein the convex protrusion includes a protrusion minima that is located in an interior region of the cylindrical outline,
wherein the outer upper electrode is an annular ring.

17. The outer upper electrode of claim 16, wherein the convex protrusion includes:
a downward sloped surface extending from the transition edge to the protrusion minima; and
an upward sloped surface extending from the protrusion minima towards the cylindrical outline, wherein the cylindrical outline includes a plurality of center lines intersecting with a plurality of radials extending from a center axis of the outer upper electrode, wherein each of the plurality of center lines intersects with the middle portion of the second top surface.

18. The outer upper electrode of claim 17,
wherein the downward sloped surface is a continuation of the sloped bottom surface at the lower edge of the outer surface of the inner upper electrode.

19. The outer upper electrode of claim 16, further comprising:
a concave portion formed on a first side with a upward sloped surface extending from the protrusion minima towards a the cylindrical outline, wherein the cylindrical outline includes a plurality of center lines intersecting with a plurality of radials extending from a center axis of the outer upper electrode, wherein each of the plurality of center lines intersects with the middle portion of the second top surface,
wherein the concave portion is located towards the outer diameter surface from the cylindrical outline.

20. The outer upper electrode of claim 19, further comprising:
an extension protruding from the outer diameter surface,
wherein the extension is formed on a second side of the concave portion.
